(19) United States
(12) Patent Application Publication
(10) Pub. No.: US 2025/0246510 A1
(43) Pub. Date: Jul. 31, 2025

(54) COOLING STRUCTURE FOR A SEMICONDUCTOR DEVICE

(71) Applicant: Rohm Co., Ltd., Kyoto-shi (JP)

(72) Inventor: Yo MOCHIZUKI, Kyoto-shi (JP)

(21) Appl. No.: 19/183,532

(22) Filed: Apr. 18, 2025

Related U.S. Application Data
(63) Continuation of application No. PCT/JP2023/036569, filed on Oct. 6, 2023.

(30) Foreign Application Priority Data
Oct. 21, 2022 (JP) 2022-168826

(51) Int. Cl. H01L 23/373; H01L 23/00; H01L 23/473; H01L 23/538; H01L 25/07

(52) U.S. Cl. CPC H01L 23/3735; H01L 23/473; H01L 23/538; H01L 25/072; H01L 24/40; H01L 2224/40137; H01L 2924/13091

(57) ABSTRACT

A cooling structure can include: a semiconductor device including a base material and a sealing resin, a cooler, and a bonding material that bonds the cooler and the base material. As viewed in a first direction, the bonding material can extend outwardly from the sealing resin. The bonding material can have a first surface and a second surface facing opposite each other in the first direction. The first surface can be in contact with the base material. The second surface can be in contact with the cooler. An area of the second surface can be larger than an area of the first surface.

### TECHNICAL FIELD

The present disclosure relates to a cooling structure for a semiconductor device.

### BACKGROUND ART

WO 2017/094370 discloses an example of a semiconductor device provided with a cooler. The cooler has a housing having a hollow region and a radiator. The housing has an opening leading to the hollow region. The radiator is attached to the housing so as to block the opening. A part of the radiator is housed in the hollow region. The semiconductor device is bonded to the part of the radiator that protrudes outside of the hollow region with an intervention of a bonding material. When a refrigerant (such as cooling water) flows into the hollow region, the refrigerant comes into contact with the radiator. This allows the semiconductor device to be cooled through the radiator.

In the configuration of the semiconductor device provided with the cooler disclosed in WO 2017/094370, it can be difficult to visually check the state of the bonding material to bond the radiator and the semiconductor device. If there is a defect in the bonding state, there is a fear that heat conduction from the semiconductor device to the radiator will be obstructed. Therefore, it is desirable to be able to visually check the bonding state between the radiator and the semiconductor device.

### BRIEF DESCRIPTION OF THE DRAWINGS

FIG. 1 is a perspective view of a cooling structure for a semiconductor device according to a first embodiment of the present disclosure.

FIG. 2 is a plan view of the cooling structure for a semiconductor device shown in FIG. 1.

FIG. 3 is a right side view of the cooling structure for a semiconductor device shown in FIG. 1.

FIG. 4 is a cross-sectional view along a line IV-IV of FIG. 2.

FIG. 5 is a cross-sectional view along a line V-V of FIG. 2.

FIG. 6 is a partial enlarged view of FIG. 4.

FIG. 7 is a partial enlarged view of FIG. 5.

FIG. 8 is a plan view of a semiconductor device provided with the cooling structure for a semiconductor device shown in FIG. 1.

FIG. 9 is a plan view corresponding to FIG. 8, with the sealing resin shown as being transparent.

FIG. 10 is a partial enlarged view of FIG. 9.

FIG. 11 is a plan view corresponding to FIG. 8, with a first conductive member shown as being transparent and the sealing resin and a second conductive member omitted.

FIG. 12 is. a right side view of the semiconductor device shown in FIG. 8

FIG. 13 is a bottom view of the semiconductor device shown in FIG. 8.

FIG. 14 is a cross-sectional view along a line XIV-XIV of FIG. 9.

FIG. 15 is a cross-sectional view along a line XV-XV of FIG. 9.

FIG. 16 is a partial enlarged view of a first element and its surrounding area shown in FIG. 15.

FIG. 17 is a partial enlarged view of a second element and its surrounding area shown in FIG. 15.

FIG. 18 is a cross-sectional view along a line XVIII-XVIII of FIG. 9.

FIG. 19 is a cross-sectional view along a line XIX-XIX of FIG. 9.

FIG. 20 is a plan view of a cooling structure for a semiconductor device according to a second embodiment of the present disclosure.

FIG. 21 is a cross-sectional view along the line XXI-XXI of FIG. 20.

FIG. 22 is a cross-sectional view along a line XXII-XXII of FIG. 20.

### DETAILED DESCRIPTION OF EMBODIMENTS

Hereinafter, preferred embodiments to carry out the present disclosure will be described based on the accompanying drawings.

### First Embodiment

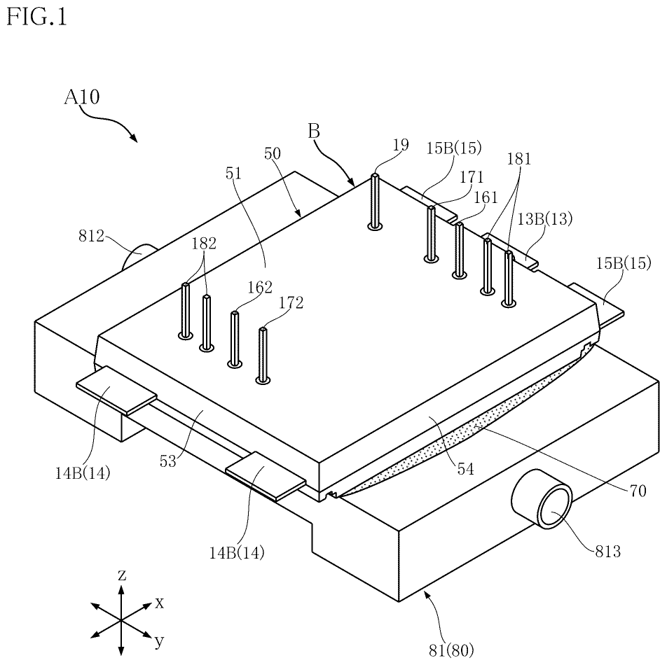

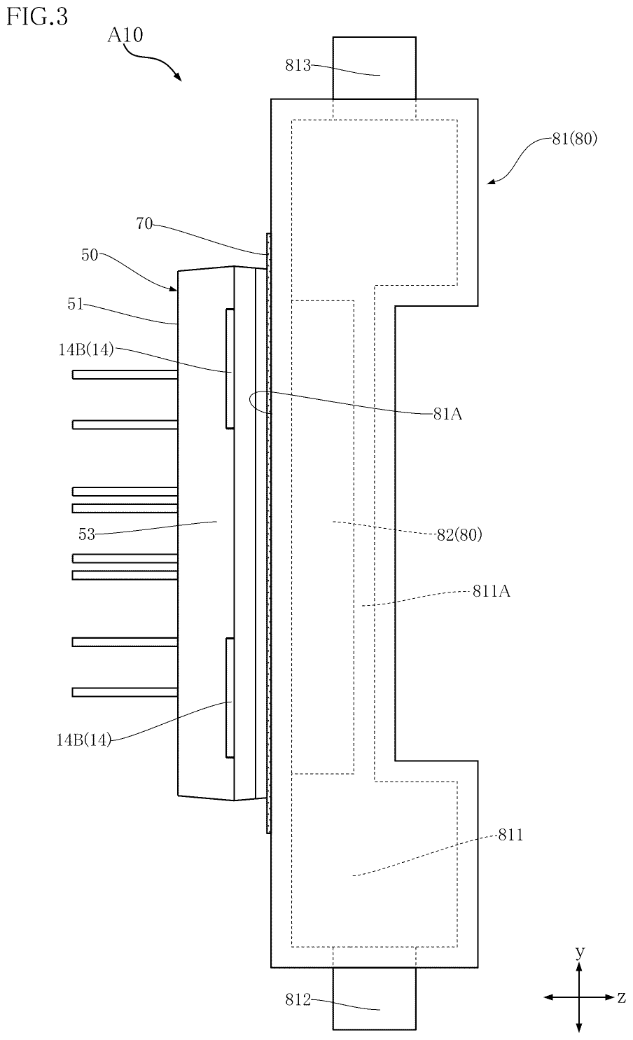

Based on FIGS. 1 to 19, a cooling structure (hereinafter referred to as a “cooling structure A10”) for a semiconductor device according to a first embodiment of the present disclosure will be described. The cooling structure A10 is provided with a semiconductor device B, a bonding material 70, and a cooler 80.

In the description of the cooling structure A10, for convenience, a normal direction of a first obverse surface 121A of a first conductive layer 121 of the semiconductor device B to be described later is referred to as a “first direction z”. A direction orthogonal to the first direction z is referred to as a “second direction x”. A direction orthogonal to the first direction z and the second direction x is called a “third direction y”.

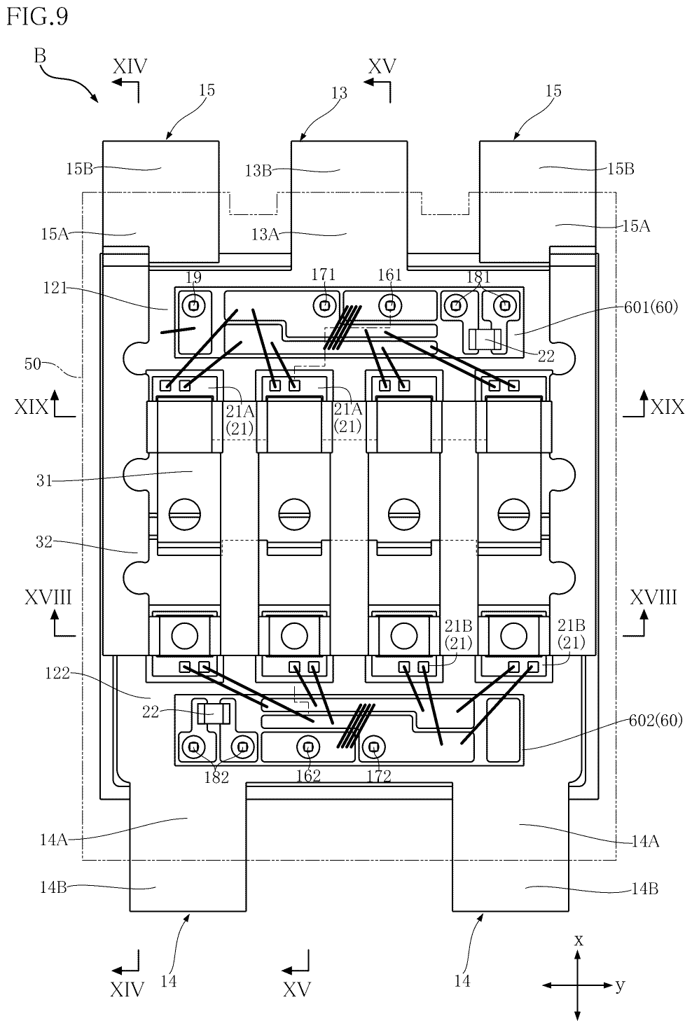

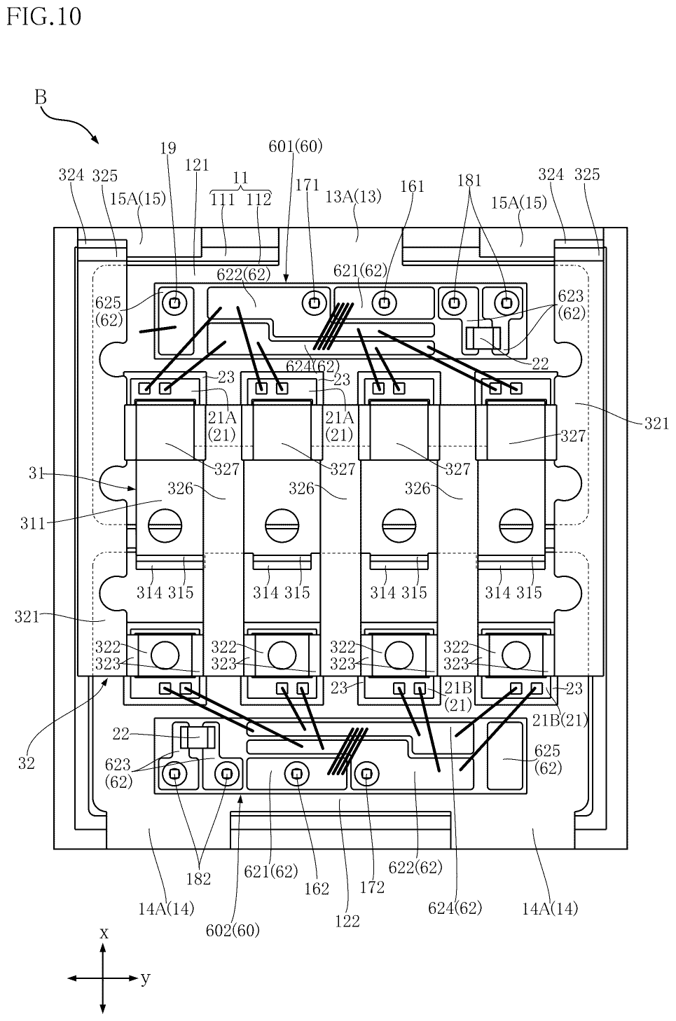

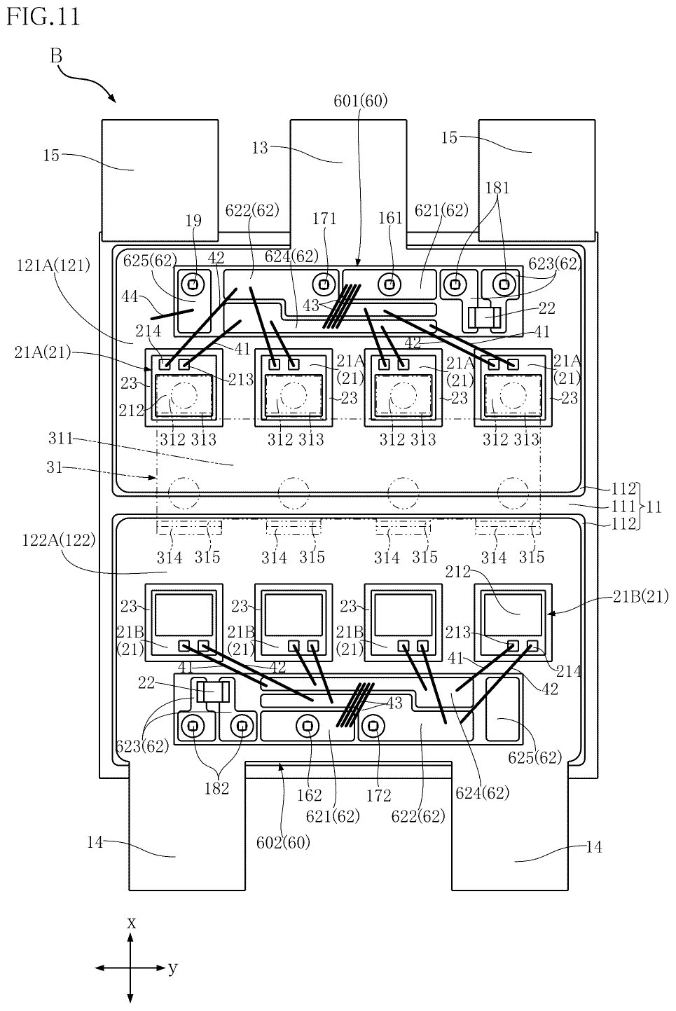

First, based on FIGS. 1 and FIGS. 8 to 19, the semiconductor device B which the cooling structure A10 is provided with will be described. The semiconductor device B can have a base material 11, a first conductive layer 121, a second conductive layer 122, a first input terminal 13, an output terminal 14, a second input terminal 15, a first signal terminal 161, a second signal terminal 162, a plurality of semiconductor elements 21, a first conductive member 31, a second conductive member 32 and a sealing resin 50. Further, the semiconductor device B can have a third signal terminal 171, a fourth signal terminal 172, a pair of fifth signal terminals 181, a pair of sixth signal terminals 182, a seventh signal terminal 19, a pair of thermistors 22, and a pair of control wirings 60. Here, in FIGS. 9 and 10, the sealing resin 50 is shown as being transparent for convenience of understanding. In FIG. 9, the sealing resin 50 as being transparent is drawn by an imaginary line (a double-dotted line). In FIG. 11, for convenience of understanding, the first conductive member 31 is shown as being transparent, and the second conductive member 32 and the sealing resin 50 are omitted. In FIG. 11, the first conductive member 31 as being transparent is drawn by an imaginary line. Further, in FIG. 9, an XV-XV line is drawn by a single-dotted line.

The semiconductor device B can be configured to convert a DC power supply voltage applied to the first input terminal 13 and the second input terminal 15 into an AC power by means of a plurality of semiconductor elements 21. The converted AC power can be input from the output terminal 14 to a power supply target such as a motor.

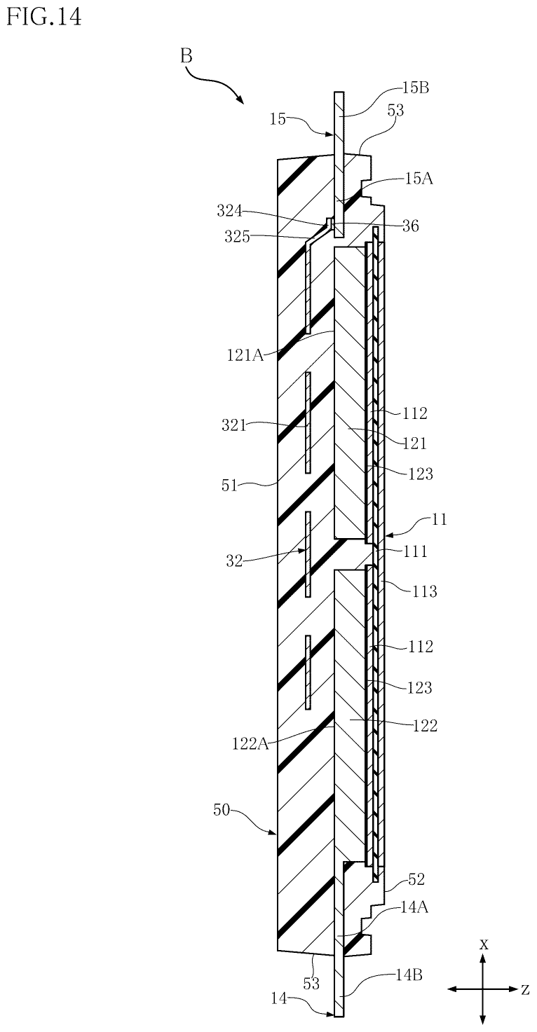

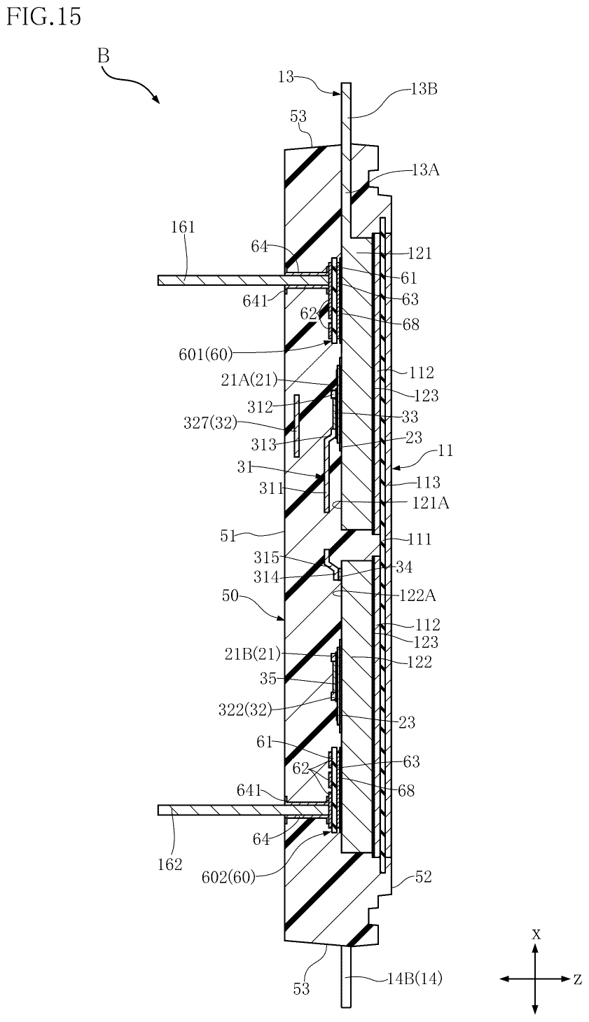

As shown in FIGS. 15 to 17, the base material 11 can be positioned opposite the plurality of semiconductor elements 21 with the first conductive layer 121 and the second conductive layer 122 in between in the first direction z. The base material 11 can support the first conductive layer 121 and the second conductive layer 122. In the semiconductor device B, the base material 11 can be constituted by a DBC (Direct Bonded can comprise) substrate. As shown in FIGS. 15 to 17, the base material 11 can include an insulating layer 111, a pair of metal layers 112, and a radiation layer 113. The base material 11 can be covered with the sealing resin 50 except for a part of the radiation layer 113.

As shown in FIGS. 15 to 17, the insulating layer 111 can include a portion interposed between the metal layer 112 and the radiation layer 113 in the first direction z. The insulating layer 111 can be a material with a relatively high thermal conductivity. The insulating layer 111 can be, for example, a ceramic containing sintered aluminum nitride (AlN). The insulating layer 111 can be constituted by an insulating resin sheet, as well as ceramics. The thickness of the insulating layer 111 can be thinner than the thickness of each of the first conductive layer 121 and the second conductive layer 122.

As shown in FIGS. 15 to 17, the pair of metal layers 112 can be positioned between the insulating layer 111, and the first conductive layer 121 or the second conductive layer 122 in the first direction z. The composition of the pair of metal layers 112 can include copper (Cu). As shown in FIG. 11, as viewed in the first direction z, each of the pair of metal layers 112 can be surrounded by a peripheral end of the insulating layer 111.

As shown in FIGS. 15 to 17, the radiation layer 113 can be positioned opposite the metal layer 112 with the insulating layer 111 in between in the first direction z. As shown in FIG. 13, the radiation layer 113 can be exposed from the sealing resin 50. The composition of the radiation layer 113 can include copper. The thickness of the radiation layer 113 can be thicker than the thickness of the insulating layer 111. As viewed in the first direction z, the radiation layer 113 can be surrounded by a peripheral end of the insulating layer 111.

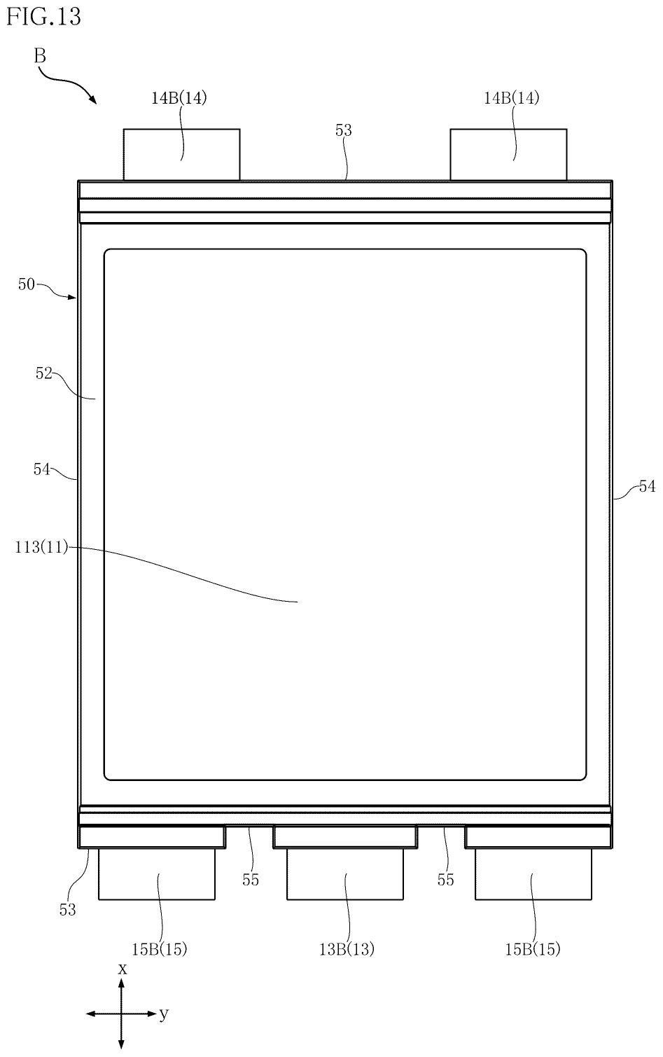

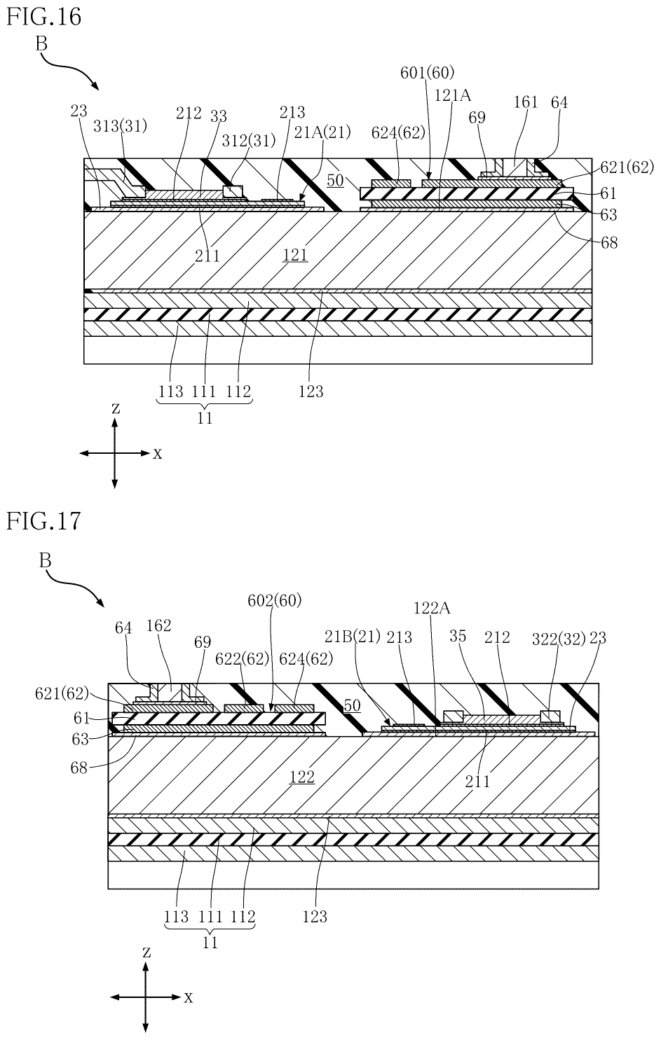

As shown in FIGS. 15 to 17, the first conductive layer 121 and the second conductive layer 122 can be bonded to the base material 11. The compositions of the first conductive layer 121 and the second conductive layer 122 can include copper. The first conductive layer 121 and the second conductive layer 122 can be separated from each other in the second direction x. As shown in FIGS. 14 and 15, the first conductive layer 121 can have a first obverse surface 121A facing the first direction z. The first obverse surface 121A can be opposed to the plurality of semiconductor elements 21. As shown in FIG. 16, the plurality of semiconductor elements 21 can be bonded to one metal layer 112 of the pair of metal layers 112 with an intervention of the first conductive layer 121 and a bonding layer 123. The bonding layer 123 can be, for example, a brazing material that includes silver (Ag) in its composition. As shown in FIGS. 14 and 15, the second conductive layer 122 can have a second obverse surface 122A facing the first direction z. The second obverse surface 122A can face the same side as the first obverse surface 121A faces in the first direction z. As shown in FIG. 17, the second conductive layer 122 can be bonded to the other metal layer 112 of the pair of metal layers 112 with an intervention of the bonding layer 123. A dimension in the first direction z of each of the first conductive layer 121 and the second conductive layer 122 can be larger than a dimension in the first direction z of the base material 11.

As shown in FIGS. 11 and 15, each of the plurality of semiconductor elements 21 can be mounted on one of the first conductive layer 121 and the second conductive layer 122. The plurality of semiconductor elements 21 can be, for example, MOSFETs (Metal-Oxide-Semiconductor Field-Effect Transistors). In addition, the plurality of semiconductor elements 21 can be switching elements such as IGBTs (Insulated Gate Bipolar Transistors) and diodes or the like. In the description of semiconductor device B, the semiconductor element 21 can be an n-channel MOSFET with a vertical structure. The plurality of semiconductor elements 21 can include a compound semiconductor substrate. The composition of the compound semiconductor substrate can include silicon carbide (SiC).

As shown in FIG. 11, in the semiconductor device B, the plurality of semiconductor elements 21 can include a plurality of first elements 21A and a plurality of second elements 21B. The structure of each of the plurality of second elements 21B can be identical to the structure of each of the plurality of first elements 21A. The plurality of first elements 21A can be mounted on the first obverse surface 121A of the first conductive layer 121. The plurality of first elements 21A can be arranged along the third direction y. The plurality of second elements 21B can be mounted on the second obverse surface 122A of the second conductive layer 122. The plurality of second elements 21B can be arranged along the third direction y.

As shown in FIG. 11 and FIGS. 16 and 17, each of the plurality of semiconductor elements 21 can have a first electrode 211, a second electrode 212, a third electrode 213 and a fourth electrode 214.

As shown in FIGS. 16 and 17, the first electrode 211 can be opposed to either the first conductive layer 121 or the second conductive layer 122. A current corresponding to the electric power before being converted by the semiconductor element 21 can flow into the first electrode 211. In other words, the first electrode 211 can correspond to a drain electrode of the semiconductor element 21.

As shown in FIGS. 16 and 17, the second electrode 212 can be located opposite the first electrode 211 in the first direction z. A current corresponding to the power after being converted by the semiconductor element 21 can flow into the second electrode 212. In other words, the second electrode 212 can correspond to a source electrode of the semiconductor element 21.

As shown in FIGS. 16 and 17, the third electrode 213 can be located on the same side as the second electrode 212 in the first direction z. A gate voltage can be applied to the third electrode 213 to drive the semiconductor element 21. In other words, the third electrode 213 can correspond to the gate electrode of the semiconductor element 21. As shown in FIG. 11, as viewed in the first direction z, an area of the third electrode 213 can be smaller than an area of the second electrode 212.

As shown in FIG. 11, the fourth electrode 214 can be located on the same side as the second electrode 212 in the first direction z and adjacent to the third electrode 213 in the third direction y. A potential of the fourth electrode 214 can be equal to a potential of the second electrode 212.

As shown in FIGS. 16 and 17, the conductive bonding layer 23 can be interposed between one of the first conductive layer 121 and the second conductive layer 122 and the first electrode 211 of one of the plurality of semiconductor elements 21. The conductive bonding layer 23 can be, for example, solder. In addition, the conductive bonding layer 23 can be configured to contain sintered metal particles. The first electrodes 211 of the plurality of first elements 21A can be conductively bonded to the first obverse surface 121A of the first conductive layer 121 with an intervention of the conductive bonding layer 23. As a result, the first electrodes 211 of the plurality of first elements 21A can conduct to the first conductive layer 121. The first electrodes 211 of the plurality of second elements 21B can be conductively bonded to the second obverse surface 122A of the second conductive layer 122 with an intervention of the conductive bonding layer 23. As a result, the first electrodes 211 of the plurality of second elements 21B can conduct to the second conductive layer 122.

As shown in FIGS. 9 and 15, the first input terminal 13 can be located opposite the second conductive layer 122 with the first conductive layer 121 in between in the second direction x and can be connected to the first conductive layer 121. As a result, the first input terminal 13 can conduct to the first electrodes 211 of the plurality of first elements 21A with an intervention of the first conductive layer 121. The first input terminal 13 can be a p-terminal (a positive pole) to which a DC power supply voltage to be converted is applied. The first input terminal 13 can extend from the first conductive layer 121 in the second direction x. The first input terminal 13 can have a covered portion 13A and an exposed portion 13B. As shown in FIG. 15, the covered portion 13A can be connected to the first conductive layer 121 and can be covered by the sealing resin 50. The covered portion 13A can be flush with the first obverse surface 121A of the first conductive layer 121. The exposed portion 13B can extend from the covered portion 13A in the second direction x and can be exposed from the sealing resin 50.

As shown in FIGS. 9 and 14, the output terminal 14 can be located opposite the first conductive layer 121 with the second conductive layer 122 in between in the second direction x and can be connected to the second conductive layer 122. As a result, the output terminal 14 can conduct to the first electrodes 211 of the plurality of second elements 21B with an intervention of the second conductive layer 122. From the output terminal 14, the AC power converted by the plurality of semiconductor elements 21 can be output. In the semiconductor device B, the output terminals 14 can include a pair of regions spaced apart from each other in the third direction y. In addition, the output terminal 14 can be a single component that does not include a pair of regions. The output terminal 14 can have a covered portion 14A and an exposed portion 14B. As shown in FIG. 14, the covered portion 14A can be connected to the second conductive layer 122 and can be covered by the sealing resin 50. The covered portion 14A can be flush with the second obverse surface 122A of the second conductive layer 122. The exposed portion 14B can extend from the covered portion 14A in the second direction x and can be exposed from the sealing resin 50.

As shown in FIGS. 9 and 14, the second input terminal 15 can be located on the same side as the first input terminal 13 with respect to the first conductive layer 121 and the second conductive layer 122 in the second direction x and can be separated from the first conductive layer 121 and the second conductive layer 122. The second input terminal 15 can conduct to the second electrodes 212 of the plurality of second elements 21B. The second input terminal 15 can be an n-terminal (a negative pole) to which a DC power supply voltage to be converted is applied. The second input terminal 15 can include a pair of regions spaced apart from each other in the third direction y. The first input terminal 13 can be located between the pair of regions in the third direction y. The second input terminal 15 can have a covered portion 15A and an exposed portion 15B. As shown in FIG. 14, the covered portion 15A can be separated from the first conductive layer 121 and can be covered by the sealing resin 50. The exposed portion 15B can extend from the covered portion 15A in the second direction x and can be exposed from the sealing resin 50.

A pair of control wirings 60 can constitute a part of a conduction path between the plurality of semiconductor elements 21, and the first signal terminal 161, the second signal terminal 162, the third signal terminal 171, the fourth signal terminal 172, the pair of fifth signal terminals 181 and the pair of sixth signal terminals 182. As shown in FIGS. 9 to 11, the pair of control wirings 60 can include a first wiring 601 and a second wiring 602. In the second direction x, the first wiring 601 can be located between the plurality of first elements 21A, and the first input terminal 13 and the second input terminal 15. The first wiring 601 can be bonded to the first obverse surface 121A of the first conductive layer 121. The first wiring 601 can also constitute a part of a conduction path between the seventh signal terminal 19 and the first conductive layer 121. In the second direction x, the second wiring 602 can be located between the plurality of second elements 21B and the output terminal 14. The second wiring 602 can be bonded to the second obverse surface 122A of the second conductive layer 122. As shown in FIGS. 16 and 17, the pair of control wirings 60 can have an insulating layer 61, a plurality of wiring layers 62, a metal layer 63, and a plurality of sleeves 64. The pair of control wirings 60 can be covered by the sealing resin 50 except for a part of each of the plurality of sleeves 64.

As shown in FIGS. 16 and 17, the insulating layer 61 can include a portion interposed between the plurality of wiring layers 62 and the metal layer 63 in the first direction z. The insulating layer 61 can be, for example, a ceramic. The insulating layer 61 can be constituted by an insulating resin sheet or the like, as well as ceramics.

As shown in FIGS. 16 and 17, the plurality of wiring layers 62 can be located on one side of the insulating layer 61 in the first direction z. The composition of the plurality of wiring layers 62 can include copper. As shown in FIG. 11, the plurality of wiring layers 62 can include a first wiring layer 621, a second wiring layer 622, a pair of third wiring layers 623, a fourth wiring layer 624 and a fifth wiring layer 625. The pair of third wiring layers 623 can be adjacent to each other in the third direction y.

As shown in FIGS. 16 and 17, the metal layer 63 can be located opposite the plurality of wiring layers 62 with the insulating layer 61 in between in the first direction z. The composition of the metal layer 63 can include copper. The metal layer 63 of the first wiring 601 can be bonded to the first obverse surface 121A of the first conductive layer 121 by the first adhesive layer 68. The metal layer 63 of the second wiring 602 can be bonded to the second obverse surface 122A of the second conductive layer 122 by the first adhesive layer 68. The first adhesive layer 68 can be a conductive or non-conductive material. The first adhesive layer 68 can be, for example, solder.

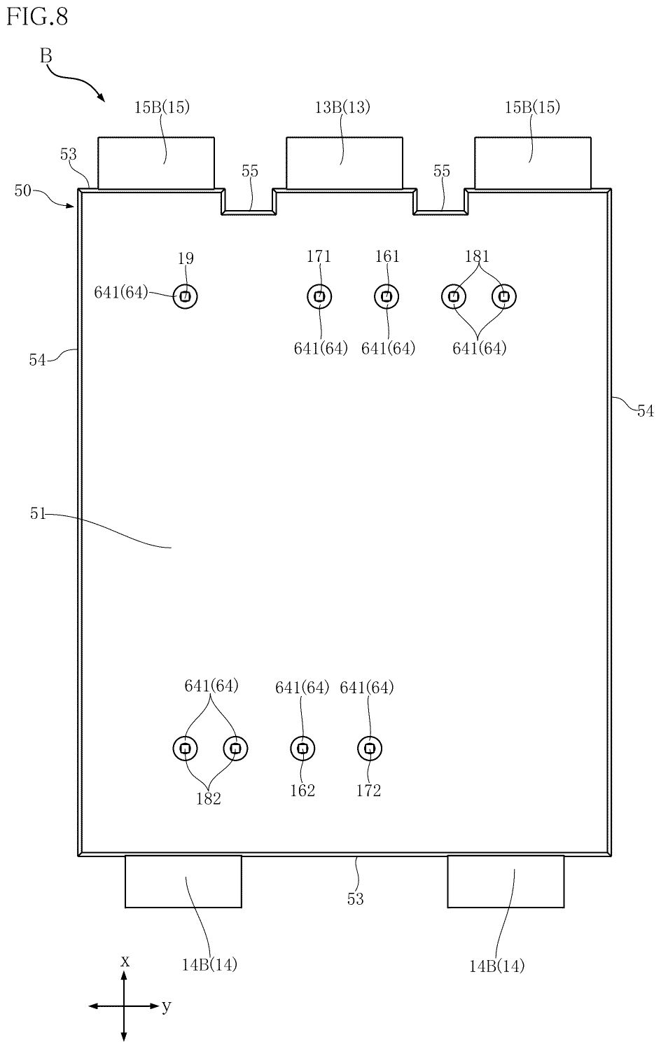

As shown in FIGS. 16 and 17, each of the plurality of sleeves 64 can be bonded to one of the plurality of wiring layers 62 by the second adhesive layer 69. The plurality of sleeves 64 can be a conductive material such as metal. Each of the plurality of sleeves 64 can be cylindrical, extending along the first direction z. One end of the plurality of sleeves 64 can be conductively bonded to one of the plurality of wiring layers 62. As shown in FIGS. 8 and 15, an end surface 641 corresponding to the other end of the plurality of sleeves 64 can be exposed from the top surface 51 of the sealing resin 50 to be described later. The second adhesive layer 69 can be conductive. The second adhesive layer 69 can be, for example, solder.

As shown in FIG. 10, one thermistor 22 of the pair of thermistors 22 can be conductively bonded to the pair of third wiring layers 623 of the first wiring 601. As shown in FIG. 10, the other thermistor 22 of the pair of thermistors 22 can be conductively bonded to the pair of third wiring layers 623 of the second wiring 602. The pair of thermistors 22 can be, for example, NTC (Negative Temperature Coefficient) thermistors, which can have a characteristic of slowly decreasing resistance with increasing temperature. The pair of thermistors 22 can be used as a sensor for detecting the temperature of the semiconductor device B.

The first signal terminal 161, the second signal terminal 162, the third signal terminal 171, the fourth signal terminal 172, the pair of fifth signal terminals 181, the pair of sixth signal terminals 182 and the seventh signal terminal 19 can each be metal pins extending in the first direction z as shown in FIG. 1. These terminals can protrude from the top surface 51 of the sealing resin 50 to be described later. Further, these terminals can be individually press-fitted into the plurality of sleeves 64 of the pair of control wirings 60. As a result, each of these terminals can be supported by one of the plurality of sleeves 64 and can conduct to one of the plurality of wiring layers 62.

As shown in FIGS. 11 and 16, the first signal terminal 161 can be press-fitted into the sleeve 64 bonded to the first wiring layer 621 of the first wiring 601 from among the plurality of sleeves 64 of the pair of control wirings 60. As a result, the first signal terminal 161 can be supported by said sleeve 64 and can conduct to the first wiring layer 621 of the first wiring 601. Further, the first signal terminal 161 can conduct to the third electrodes 213 of the plurality of first elements 21A. A gate voltage can be applied to the first signal terminal 161 to drive the plurality of first elements 21A.

As shown in FIGS. 11 and 17, the second signal terminal 162 can be press-fitted into the sleeve 64 bonded to the first wiring layer 621 of the second wiring 602 from among the plurality of sleeves 64 of the pair of control wirings 60. As a result, the second signal terminal 162 can be supported by said sleeve 64 and can conduct to the first wiring layer 621 of the second wiring 602. Further, the second signal terminal 162 can conduct to the third electrodes 213 of the plurality of second elements 21B. A gate voltage can be applied to the second signal terminal 162 to drive the plurality of second elements 21B.

As shown in FIG. 8, the third signal terminal 171 can be located adjacent to the first signal terminal 161 in the third direction y. As shown in FIG. 11, the third signal terminal 171 can be press-fitted into the sleeve 64 bonded to the second wiring layer 622 of the first wiring 601 from among the plurality of sleeves 64 of the pair of control wirings 60. As a result, the third signal terminal 171 can be supported by said sleeve 64 and can conduct to the second wiring layer 622 of the first wiring 601. Further, the third signal terminal 171 can conduct to the fourth electrodes 214 of the plurality of first elements 21A. A voltage corresponding to the maximum current among the currents flowing into the fourth electrode 214 of each of the plurality of first elements 21A can be applied to the third signal terminal 171.

As shown in FIG. 8, the fourth signal terminal 172 can be located adjacent to the second signal terminal 162 in the third direction y. As shown in FIG. 11, the fourth signal terminal 172 can be press-fitted into the sleeve 64 bonded to the second wiring layer 622 of the second wiring 602 from among the plurality of sleeves 64 of the pair of control wirings 60. As a result, the fourth signal terminal 172 can be supported by said sleeve 64 and can conduct to the second wiring layer 622 of the second wiring 602. Further, the fourth signal terminal 172 can conduct to the fourth electrodes 214 of the plurality of second elements 21B. The voltage corresponding to the maximum current among the currents flowing into the fourth electrode 214 of each of the plurality of second elements 21BA can be applied to the fourth signal terminal 172.

As shown in FIG. 8, the pair of fifth signal terminals 181 can be located opposite the third signal terminal 171 with the first signal terminal 161 in between in the third direction y. The pair of fifth signal terminals 181 can be adjacent to each other in the third direction y. As shown in FIG. 11, the pair of fifth signal terminals 181 can be individually press-fitted into the pair of sleeves 64 that are bonded to the pair of third wiring layers 623 of the first wiring 601 from among the plurality of sleeves 64 of the pair of control wirings 60. As a result, the pair of fifth signal terminals 181 can be supported by said pair of sleeves 64 and can conduct to the pair of third wiring layers 623 of the first wiring 601. Further, the pair of fifth signal terminals 181 can conduct to the thermistor 22 conductively bonded to the pair of third wiring layers 623 of the first wiring 601 from among the pair of thermistors 22.

As shown in FIG. 8, the pair of sixth signal terminals 182 can be located opposite the fourth signal terminal 172 with the second signal terminal 162 in between in the third direction y. The pair of sixth signal terminals 182 can be adjacent to each other in the third direction y. As shown in FIG. 11, the pair of sixth signal terminals 182 can be individually press-fitted into the pair of sleeves 64 bonded to the pair of third wiring layers 623 of the second wiring 602 from among the plurality of sleeves 64 of the pair of control wiring 60. As a result, the pair of sixth signal terminals 182 can be supported by said pair of sleeves 64 and can conduct to the pair of third wiring layers 623 of the second wiring 602. Further, the pair of sixth signal terminals 182 can conduct to the thermistor 22 conductively bonded to the pair of third wiring layers 623 of the second wiring 602 from among the pair of thermistors 22.

As shown in FIG. 8, the seventh signal terminal 19 can be located opposite the first signal terminal 161 with the third signal terminal 171 in between in the third direction y. As shown in FIG. 11, the seventh signal terminal 19 can be press-fitted into the sleeve 64 bonded to the fifth wiring layer 625 of the first wiring 601 from among the plurality of sleeves 64 of the pair of control wirings 60. As a result, the seventh signal terminal 19 can be supported by said sleeve 64 and can conduct to the fifth wiring layer 625 of the first wiring 601. Further, the seventh signal terminal 19 can conduct to the first conductive layer 121. A voltage corresponding to a DC power input to the first input terminal 13 and the second input terminal 15 can be applied to the seventh signal terminal 19.

As shown in FIG. 11, the plurality of first wires 41 can be conductively bonded to the third electrodes 213 of the plurality of first elements 21A and the fourth wiring layer 624 of the first wiring 601. As shown in FIG. 11, the plurality of third wires 43 can be conductively bonded to the fourth wiring layer 624 of the first wiring 601 and the first wiring layer 621 of the first wiring 601. As a result, the first signal terminal 161 can conduct to the third electrodes 213 of the plurality of first elements 21A. The composition of the plurality of first wires 41 and the plurality of third wires 43 can include gold (Au). In addition, the composition of the plurality of first wires 41 and plurality of third wires 43 can include copper or aluminum (Al).

Further, as shown in FIG. 11, the plurality of first wires 41 can be conductively bonded to the third electrodes 213 of the plurality of second elements 21B and the fourth wiring layer 624 of the second wiring 602. Further, as shown in FIG. 11, the plurality of third wires 43 can be conductively bonded to the fourth wiring layer 624 of the second wiring 602 and the first wiring layer 621 of the second wiring 602. As a result, the second signal terminal 162 can conduct to the third electrodes 213 of the plurality of second elements 21B.

As shown in FIG. 11, the plurality of second wires 42 can be conductively bonded to the fourth electrodes 214 of the plurality of first elements 21A and the second wiring layer 622 of the first wiring 601. As a result, the third signal terminal 171 can conduct to the fourth electrodes 214 of the plurality of first elements 21A. Further, as shown in FIG. 11, the plurality of second wires 42 can be conductively bonded to the fourth electrodes 214 of the plurality of second elements 21B and the second wiring layer 622 of the second wiring 602. As a result, the fourth signal terminal 172 can conduct to the fourth electrodes 214 of the plurality of second elements 21B. The composition of the plurality of second wires 42 can include gold. In addition, the composition of the plurality of second wires 42 can include copper or aluminum.

As shown in FIG. 11, the fourth wire 44 can be conductively bonded to the fifth wiring layer 625 of the first wiring 601 and the first obverse surface 121A of the first conductive layer 121. As a result, the seventh signal terminal 19 can conduct to the first conductive layer 121. The composition of the fourth wire 44 can include gold. In addition, the composition of the fourth wire 44 can include copper or aluminum.

As shown in FIGS. 11 and 16, the first conductive member 31 can be conductively bonded to the second electrodes 212 of the plurality of first elements 21A and the second obverse surface 122A of the second conductive layer 122. As a result, the second electrodes 212 of the plurality of first elements 21A can conduct to the second conductive layer 122. The composition of the first conductive member 31 can include copper. The first conductive member 31 can be a metal clip. As shown in FIG. 11, the first conductive member 31 can have a body portion 311, a plurality of first bonding portions 312, a plurality of first coupling portions 313, a second bonding portion 314, and a second coupling portion 315.

The body portion 311 can constitute a main part of the first conductive member 31. As shown in FIG. 11, the body portion 311 can extend in the third direction y. As shown in FIG. 15, the body portion 311 can straddle a region between the first conductive layer 121 and the second conductive layer 122.

As shown in FIG. 16, the plurality of first bonding portions 312 can be individually bonded to the second electrodes 212 of the plurality of first elements 21A. Each of the plurality of first bonding portions 312 can be opposed to the second electrode 212 of one of the plurality of first elements 21A.

As shown in FIG. 11, the plurality of first coupling portions 313 can be connected to the body portion 311 and the plurality of first bonding portions 312. The plurality of first coupling portions 313 can be separated from each other in the third direction y. As shown in FIG. 15, as viewed in the third direction y, the plurality of first coupling portions 313 can be inclined to be separated from the first obverse surface 121A of the first conductive layer 121 as it extends from the plurality of first bonding portions 312 toward the body portion 311.

As shown in FIGS. 11 and 15, the second bonding portion 314 can be bonded to the second obverse surface 122A of the second conductive layer 122. The second bonding portion 314 can be opposed to the second obverse surface 122A. The second bonding portion 314 can extend in the third direction y. A dimension in the third direction y of the second bonding portion 314 can be equal to a dimension in the third direction y of the body portion 311.

As shown in FIGS. 11 and 15, the second coupling portion 315 can be connected to the body portion 311 and the second bonding portion 314. As viewed in the third direction y, the second coupling portion 315 can be inclined to be separated from the second obverse surface 122A of the second conductive layer 122 as it extends from the second bonding portion 314 toward the body portion 311. A dimension in the third direction y of the second coupling portion 315 can be equal to a dimension in the third direction y of the body portion 311.

As shown in FIGS. 15, 16 and 19, the semiconductor device B can further have a first conductive bonding layer 33. The first conductive bonding layer 33 can be interposed between the second electrodes 212 of the plurality of first elements 21A and the plurality of first bonding portions 312. The first conductive bonding layer 33 can conductively bond the second electrodes 212 of the plurality of first elements 21A and the plurality of first bonding portions 312. The first conductive bonding layer 33 can be, for example, solder. In addition, the first conductive bonding layer 33 can contain sintered metal particles.

As shown in FIG. 15, the semiconductor device B can further have a second conductive bonding layer 34. The second conductive bonding layer 34 can be interposed between the second obverse surface 122A of the second conductive layer 122 and the second bonding portion 314. The second conductive bonding layer 34 can conductively bond the second obverse surface 122A and the second bonding portion 314. The second conductive bonding layer 34 can be, for example, solder. In addition, the second conductive bonding layer 34 can contain sintered metal particles.

As shown in FIGS. 10 and 17, the second conductive member 32 can be conductively bonded to the second electrodes 212 of the plurality of second elements 21B and the covered portion 15A of the second input terminal 15. As a result, the second electrodes 212 of the plurality of second elements 21B can conduct to the second input terminal 15. The composition of the second conductive member 32 can include copper. The second conductive member 32 can be a metal clip. As shown in FIG. 10, the second conductive member 32 can have a pair of body portions 321, a plurality of third bonding portions 322, a plurality of third coupling portions 323, a pair of fourth bonding portions 324, a pair of fourth coupling portions 325, a plurality of intermediate portions 326, and a plurality of transverse beam portions 327.

As shown in FIG. 10, the pair of body portions 321 can be separated from each other in the third direction y. The pair of body portions 321 can extend in the second direction x. As shown in FIG. 14, the pair of body portions 321 can be positioned parallel to the first obverse surface 121A of the first conductive layer 121 and the second obverse surface 122A of the second conductive layer 122. The pair of body portions 321 can be more separated from the first obverse surface 121A and the second obverse surface 122A than the body portion 311 of the first conductive member 31 is.

As shown in FIG. 10, the plurality of intermediate portions 326 can be separated from each other in the third direction y and can be located between the pair of body portions 321 in the third direction y. The plurality of intermediate portions 326 can extend in the second direction x. A dimension in the second direction x of each of the plurality of intermediate portions 326 can be smaller than a dimension in the second direction x of each of the pair of body portions 321.

As shown in FIG. 17, the plurality of third bonding portions 322 can be individually bonded to the second electrodes 212 of the plurality of second elements 21B. Each of the plurality of third bonding portions 322 can be opposed to the second electrode 212 of one of the plurality of second elements 21B.

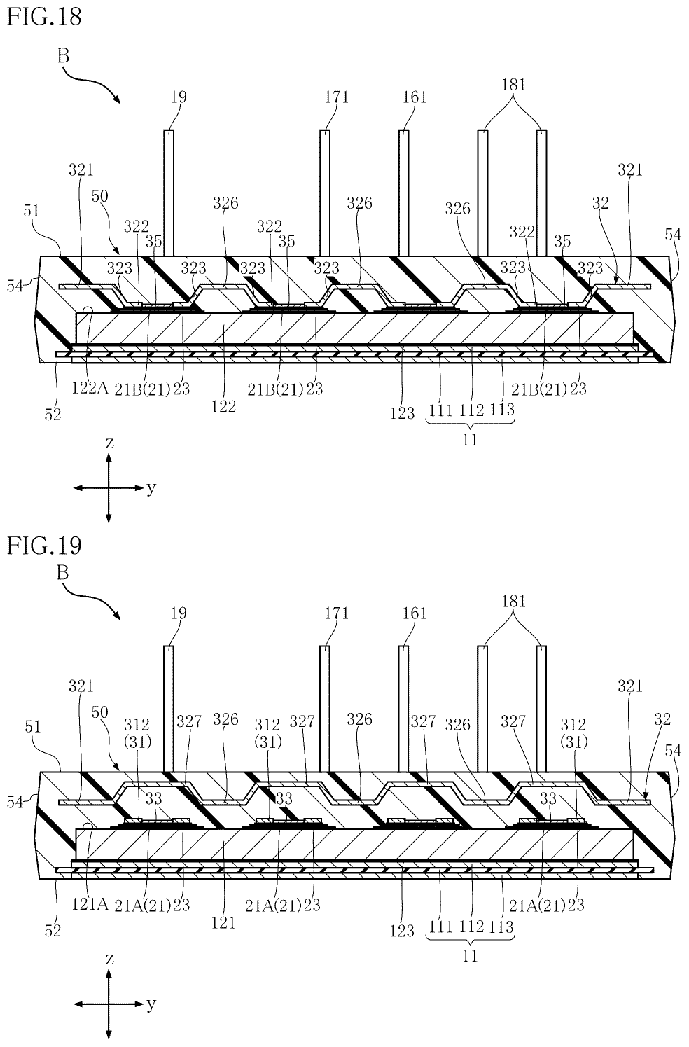

As shown in FIGS. 10 and 18, the plurality of third coupling portions 323 can be connected to both sides of the plurality of third bonding portions 322 in the third direction y. Further, the plurality of third coupling portions 323 can be connected to either of the pair of body portions 321 and the plurality of intermediate portions 326. As viewed in the second direction x, each of the plurality of third coupling portions 323 can be inclined to be separated from the second obverse surface 122A of the second conductive layer 122 as it extends from one of the plurality of third bonding portions 322 toward one of the pair of body portions 321 and the plurality of intermediate portions 326.

As shown in FIGS. 10 and 14, the pair of fourth bonding portions 324 can be bonded to the covered portion 15A of the second input terminal 15. The pair of fourth bonding portions 324 can be opposed to the covered portion 15A.

As shown in FIGS. 10 and 14, the pair of fourth coupling portions 325 can be connected to the pair of body portions 321 and the pair of fourth bonding portions 324. As viewed in the third direction y, the pair of fourth coupling portions 325 can be inclined to be separated in the first direction z from the first obverse surface 121A of the first conductive layer 121 as it extends from the pair of fourth bonding portions 324 toward the pair of body portions 321.

As shown in FIGS. 10 and 19, the plurality of transverse beam portions 327 can be arranged along the third direction y. As viewed in the first direction z, the plurality of transverse beam portions 327 can include regions that individually overlap the plurality of first bonding portions 312 of the first conductive member 31. Both sides in the third direction y of the plurality of transverse beam portions 327 that are located in the middle in the third direction y can lead to the plurality of intermediate portions 326 from among the plurality of transverse beam portions 327. Both sides in the third direction y of the remaining two transverse beam portions 327 from among the plurality of transverse beam portions 327 can be connected to one of the pair of body portions 321 and one of the plurality of intermediate portions 326. As viewed in the second direction x, the plurality of transverse beam portions 327 can be convex in the first direction z toward the side toward which the first obverse surface 121A of the first conductive layer 121 faces.

As shown in FIGS. 15, 17 and 18, the semiconductor device B can further have a third conductive bonding layer 35. The third conductive bonding layer 35 can be interposed between the second electrodes 212 of the plurality of second elements 21B and the plurality of third bonding portions 322. The third conductive bonding layer 35 can conductively bond the second electrodes 212 of the plurality of second elements 21B and the plurality of third bonding portions 322. The third conductive bonding layer 35 can be, for example, solder. In addition, the third conductive bonding layer 35 can contain sintered metal particles.

As shown in FIG. 14, the semiconductor device B can further have a fourth conductive bonding layer 36. The fourth conductive bonding layer 36 can be interposed between the covered portion 15A of the second input terminal 15 and the pair of fourth bonding portions 324. The fourth conductive bonding layer 36 can conductively bond the covered portion 15A and the pair of fourth bonding portions 324. The fourth conductive bonding layer 36 can be, for example, solder. In addition, the fourth conductive bonding layer 36 can contain sintered metal particles.

As shown in FIGS. 14, 15, 18, and 19, the sealing resin 50 can cover the first conductive layer 121, the second conductive layer 122, the plurality of semiconductor elements 21, the first conductive member 31 and the second conductive member 32. Further, the sealing resin 50 can cover a part of each of the base material 11, the first input terminal 13, the output terminal 14, and the second input terminal 15. The sealing resin 50 can have electrically insulating properties. The sealing resin 50 can be a material including, for example, black epoxy resin. As shown in FIG. 8 and FIGS. 12 to 15, the sealing resin 50 can have a top surface 51, a bottom surface 52, a pair of first lateral surfaces 53, a pair of second lateral surfaces 54, and a pair of recesses 55.

As shown in FIGS. 14 and 15, the top surface 51 can face the same side as the first obverse surface 121A of the first conductive layer 121 faces in the first direction z. As shown in FIGS. 14 and 15, the bottom surface 52 can face a side opposite to the side the top surface 51 faces in the first direction z. As shown in FIG. 13, the radiation layer 113 of the base material 11 can be exposed from the bottom surface 52.

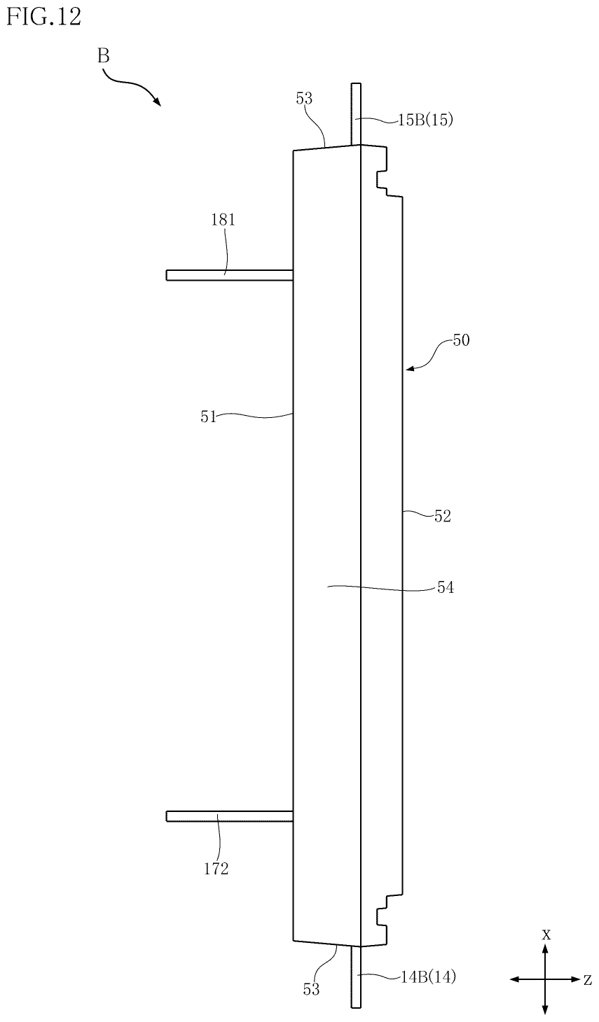

As shown in FIGS. 8 and 12, the pair of first lateral surfaces 53 can be separated from each other in the second direction x. The pair of first lateral surfaces 53 can face the second direction x and extend in the third direction y. The pair of first lateral surfaces 53 can be continuous to the top surface 51. From one first lateral surface 53 of the pair of first lateral surfaces 53, an exposed portion 13B of the first input terminal 13 and exposed portion 15B of the second input terminal 15 can be exposed. From the other first lateral surface 53 of the pair of first lateral surfaces 53, the exposed portion 14B of the output terminal 14 can be exposed.

As shown in FIGS. 8 and 13, the pair of second lateral surfaces 54 can be separated from each other in the third direction y. The pair of second lateral surfaces 54 can face opposite each other in the third direction y and can extend in the second direction x. The pair of second lateral surfaces 54 can be continuous to the top surface 51 and the bottom surface 52.

As shown in FIGS. 8 and 13, the pair of recesses 55 can be recessed in the second direction x from the first lateral surface 53 on which the exposed portion 13B of the first input terminal 13 and the exposed portion 15B of the second input terminal 15 are exposed from among the pair of first lateral surfaces 53. The pair of recesses 55 can lead from the top surface 51 to the bottom surface 52 in the first direction z. The pair of recesses 55 can be located on both sides in the third direction y of the first input terminal 13.

Subsequently, based on FIGS. 1 to 7, the bonding material 70 and the cooler 80 that the cooling structure A10 is provided with are described.

The cooler 80 can be utilized to cool the semiconductor device B. The cooler 80 can be made of a material containing, for example, aluminum.

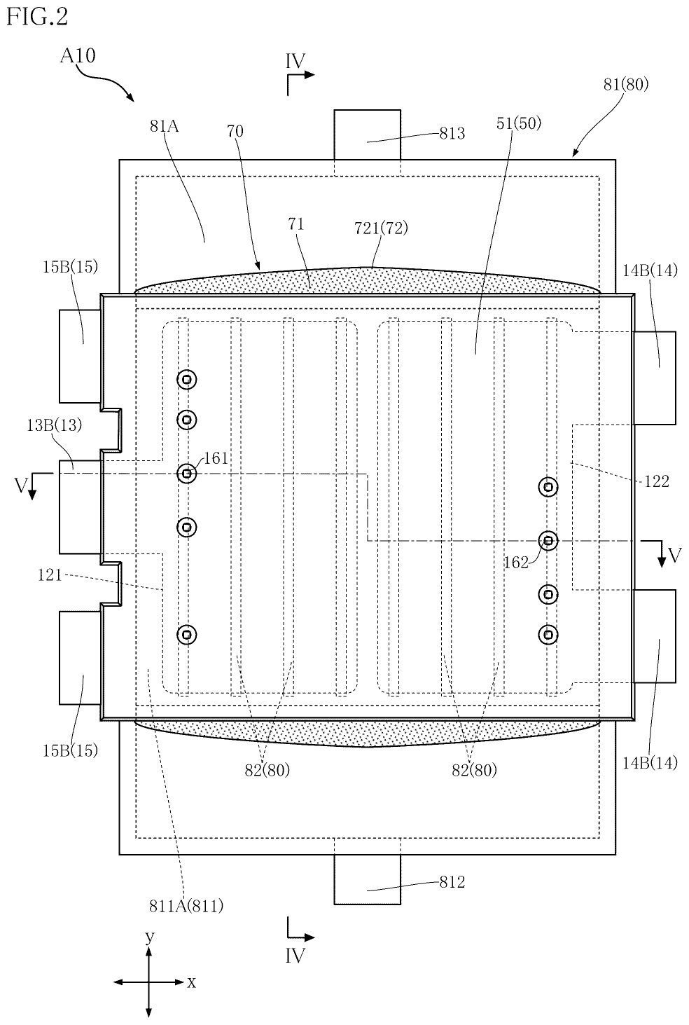

As shown in FIGS. 2 to 5, the cooler 80 can have a housing 81 and a heat dissipating member 82. The housing 81 can have a hollow portion 811, an inlet 812, and an outlet 813. The hollow portion 811 can be located inside the housing 81. The inlet 812 and outlet 813 can be connected to hollow portion 811. The inlet 812 and outlet 813 can be located opposite each other in the third direction y with respect to the hollow portion 811. In the cooler 80, the refrigerant can be configured to flow from the inlet 812 through the hollow portion 811 to the outlet 813.

As shown in FIGS. 2 to 5, the housing 81 can have a mounting surface 81A facing the first direction z. The mounting surface 81A can be opposed to the radiation layer 113 of the base material 11.

As shown in FIGS. 2 to 5, the hollow portion 811 of the housing 81 can include a steeply contracted portion 811A. The steeply contracted portion 811A refers to a part of the hollow portion 811 that is along the direction orthogonal to the first direction z and has the smallest cross-sectional area in the section from the inlet 812 to the outlet 813.

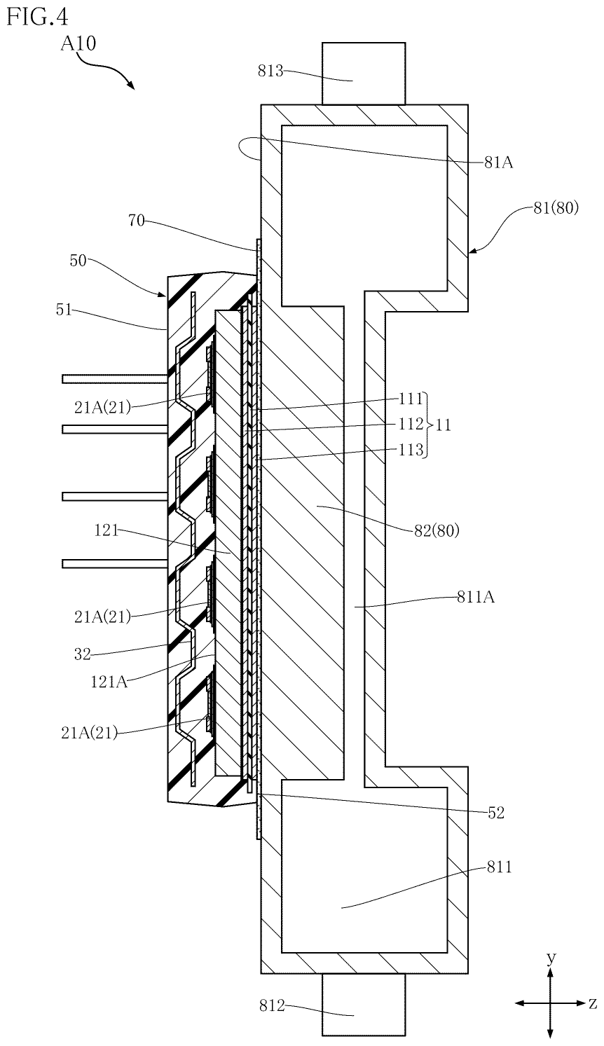

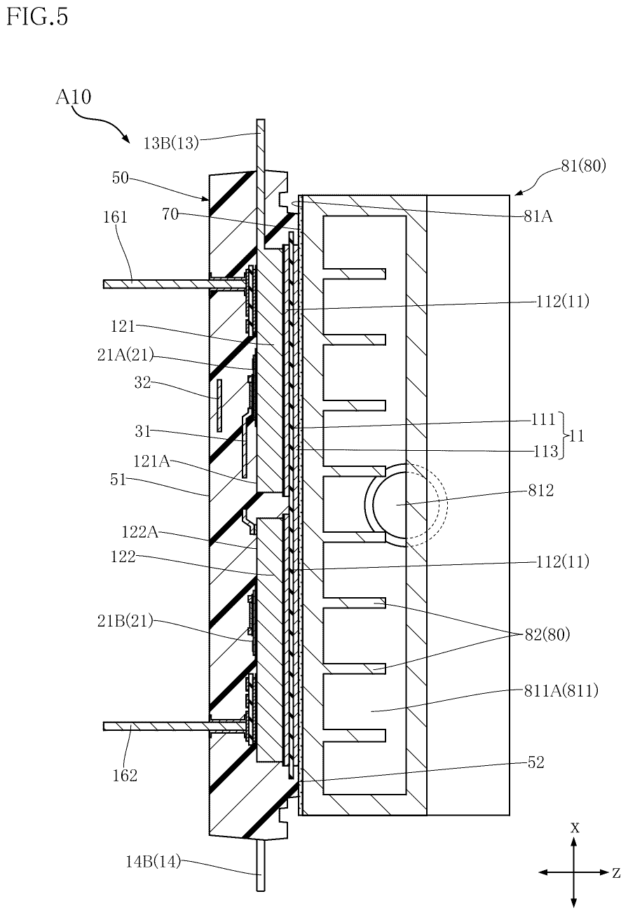

As shown in FIGS. 2 to 5, the heat dissipating member 82 can be housed in the steeply contracted portion 811A of the hollow portion 811 of the housing 81. The heat dissipating member 82 can be connected to the housing 81. As shown in FIGS. 2 and 5, the heat dissipating member 82 can be a plurality of fins spaced apart from one another in the second direction x. As shown in FIGS. 2 and 4, each of the plurality of fins can extend in the third direction y. Thus, each of the plurality of fins can extend in a direction orthogonal to the first direction z and along the section from the inlet 812 to the outlet 813.

As shown in FIG. 2, as viewed in the first direction z, each of the first conductive layer 121 and the second conductive layer 122 can overlap the steeply contracted portion 811A of the hollow portion 811 of the housing 81. Further, as viewed in the first direction z, each of the first conductive layer 121 and the second conductive layer 122 can overlap the heat dissipating member 82.

As shown in FIGS. 4 and 5, the bonding material 70 can bond the housing 81 of the cooler 80 and the radiation layer 113 of the base material 11. As shown in FIG. 2, as viewed in the first direction z, the bonding material 70 can extend outward from the sealing resin 50.

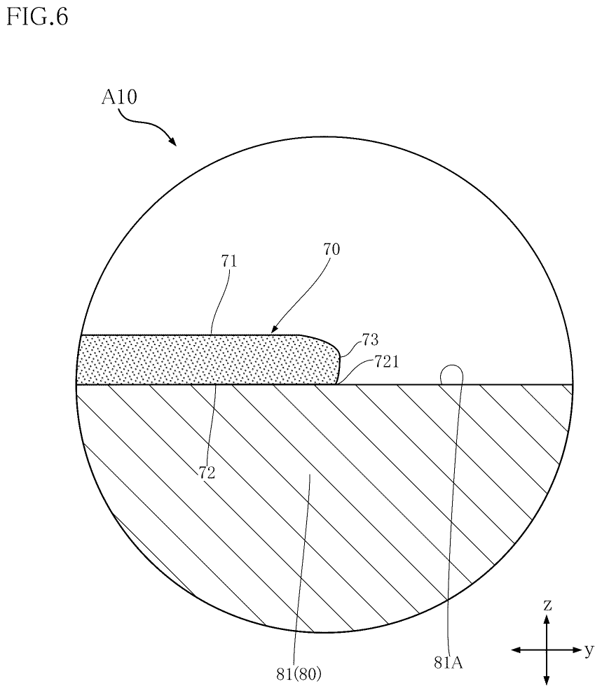

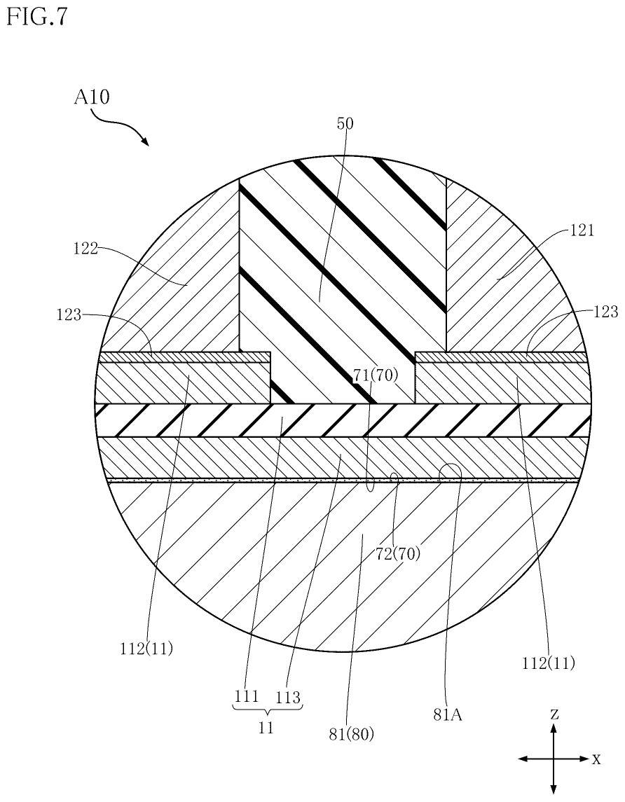

As shown in FIGS. 6 and 7, the bonding material 70 can have a first surface 71 and a second surface 72 facing opposite each other in the first direction z. The first surface 71 can be in contact with the radiation layer 113 of the base material 11. The second surface 72 can be in contact with the mounting surface 81A of the housing 81 of the cooler 80. An area of the second surface 72 can be larger than an area of the first surface 71. As shown in FIG. 2, the entire first surface 71 can overlap the second surface 72. As shown in FIGS. 4 and 6, the first surface 71 can contact the bottom surface 52 of the sealing resin 50.

As shown in FIG. 2, the peripheral end 721 of the second surface 72 can include a section that is a convex curve.

As shown in FIG. 6, the bonding material 70 can have an end surface 73 that faces a direction orthogonal to the first direction z. The end surface 73 can bulge toward the outside of the bonding material 70.

As shown in FIG. 7, a dimension in the first direction z of the bonding material 70 can be smaller than a dimension in the first direction z of the radiation layer 113 of the base material 11.

The dimension in the first direction z of the bonding material 70 can be smaller than or equal to one tenth of the dimension in the first direction z of the radiation layer 113.

As shown in FIG. 2, as viewed in the first direction z, each of the exposed portion 13B of the first input terminal 13, the exposed portions 14B of the output terminal 14, and the exposed portion 15B of the second input terminal 15 can be separated from the cooler 80 and the bonding material 70.

As shown in FIGS. 1 and 2, in the cooling structure A10, the entire top surface 51 of the sealing resin 50 can be exposed to the outside.

Further, with respect to the cooling structure A10, the following findings have been obtained from the analysis performed by the inventor of the present disclosure. In the case where the Young's modulus of the insulating layer 111 of the base material 11 is 300 GPa or higher and the difference in linear expansion coefficient between the cooler 80 and the insulating layer 111 is 12×10⁻⁶ (1/K) or higher, it is preferable that the dimension in the first direction z of the bonding material 70 be set to 40 μm or more. Further, in the case where the Young's modulus of the insulating layer 111 is 30 GPa or less and the difference in linear expansion coefficient between the cooler 80 and the insulating layer 111 is 50×10⁻⁶ (1/K) or less, it is preferable that the dimension in the first direction z of the bonding material 70 be set to 20 μm or more. When the thermal stress caused by the heat generated from the semiconductor device B acts on the bonding material 70, the maximum thermal stress can thereby be less than the yield stress of the bonding material 70.

Subsequently, the effect of the cooling structure A10 will be described.

The cooling structure A10 can be provided with a semiconductor device B having the base material 11 and a sealing resin 50, a cooler 80, and a bonding material 70 that bonds the cooler 80 and the base material 11. As viewed in the first direction z, the bonding material 70 can extend outwardly from the sealing resin 50. The bonding material 70 can have a first surface 71 in contact with the base material 11 and a second surface 72 in contact with the cooler 80. The area of the second surface 72 can be checked by visually seeing the state of the bonding material 70, by adopting the present configuration to allow the area of the second surface 72 to be larger than the area of the first surface 71. Further, since the area of the second surface 72 is larger than the area of the first surface 71, heat can easily diffuse in the bonding material 70 in a direction orthogonal to the first direction z. This can reduce the thermal resistance in the first direction z of the bonding material 70. Therefore, according to this configuration, in the cooling structure A10, it is possible to easily check the bonding state of the semiconductor device B with respect to the cooler 80, while increasing the cooling efficiency of the semiconductor device B.

As viewed in the first direction z, the entire first surface 71 of the bonding material 70 can overlap the second surface 72 of the bonding material 70. By adopting this configuration, heat can be diffused more uniformly in the bonding material 70 in a direction orthogonal to the first direction z. This can suppress uneven distribution of the thermal resistance in a direction orthogonal to the first direction z (the thermal resistance of the first direction z) of the bonding material 70.

The first surface 71 of the bonding material 70 can contact the bottom surface 52 of the sealing resin 50. By adopting this configuration, the contact area of the bonding material 70 with respect to the semiconductor device B can be increased. As a result, the bonding strength between the cooler 80 and the semiconductor device B can be improved.

As viewed in the first direction z, the peripheral end 721 of the second surface 72 of the bonding material 70 can include a section that is a convex curve. Further, the end surface 73 of the bonding material 70 can bulge toward the outside of the bonding material 70. This configuration implies that the viscosity of the bonding material 70 is relatively large and that a sufficient compressive stress in the first direction z is applied to the bonding material 70 when bonding the semiconductor device B to the cooler 80. This configuration is thus an indicator that the bonding state between the cooler 80 and the semiconductor device B is favorable.

In the cooling structure A10, the entire top surface 51 of the sealing resin 50 can be exposed to the outside. This configuration implies that an attachment member for fixing the semiconductor device B to the cooler 80 is not necessary. This can suppress a decrease in the insulation breakdown voltage of the semiconductor device B, especially when the attachment member is made of metal.

The semiconductor device B can further have the first input terminal 13 that conducts to the first conductive layer 121 and the second input terminal 15 that conducts to the second conductive layer 122. As viewed in the first direction z, each of the exposed portion 13B of the first input terminal 13 and the exposed portion 15B of the second input terminal 15 can be separated from the cooler 80 and the bonding material 70. By adopting this configuration, a decrease in the insulation breakdown voltage of the semiconductor device B can be suppressed.

The dimension in the first direction z of each of the first conductive layer 121 and the second conductive layer 122 can be larger than the dimension in the first direction z of the base material 11. By adopting this configuration, the heat diffusion is facilitated in each of the first conductive layer 121 and the second conductive layer 122 in a direction orthogonal to the first direction z. As a result, the thermal resistance in the first direction z of each of the first conductive layer 121 and the second conductive layer 122 can be reduced.

In the cooling structure A10, the cooler 80 can have the housing 81 with which the second surface 72 of the bonding material 70 contacts. The housing 81 can have the hollow portion 811 located inside the housing 81, and the inlet 812 and the outlet 813 leading to the hollow portion 811. As viewed in the first direction z, the first conductive layer 121 can overlap the hollow portion 811. By adopting this configuration, a refrigerant can flow into the hollow portion 811, and thus the cooling efficiency of the semiconductor device B can be improved.

The hollow portion 811 of the housing 81 can include the steeply contracted portion 811A that is along a direction orthogonal to the first direction z and has a minimum cross-sectional area in the section from the inlet 812 to the outlet 813. As viewed in the first direction z, the first conductive layer 121 can overlap the steeply contracted portion 811A. By adopting this configuration, the flow velocity of the refrigerant in the steeply contracted portion 811A can be increased, and thus the cooling efficiency of the semiconductor device B can be further improved.

The cooler 80 can have the heat dissipating member 82 that is housed in the steeply contracted portion 811A of the housing 81 and that is connected to the housing 81. As viewed in the first direction z, each of the first conductive layer 121 and the second conductive layer 122 can overlap the heat dissipating member 82. By adopting this configuration, the contact area of the cooler 80 with respect to the refrigerant is expanded, and thus the cooling efficiency of the semiconductor device B can be further improved.

The heat dissipating member 82 can include the plurality of fins. Each of the plurality of fins can extend in a direction orthogonal to the first direction z and along the section from the inlet 812 to the outlet 813. By adopting this configuration, the obstruction of the flow of the refrigerant in the steeply contracted portion 811A of the cooler 80 can be suppressed. Second embodiment:

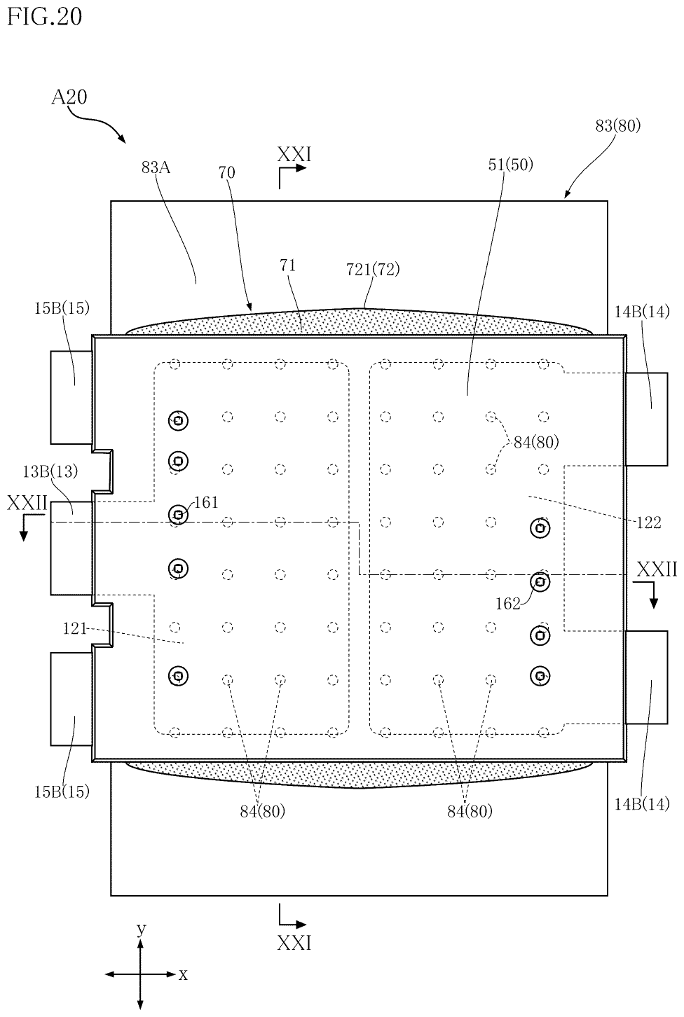

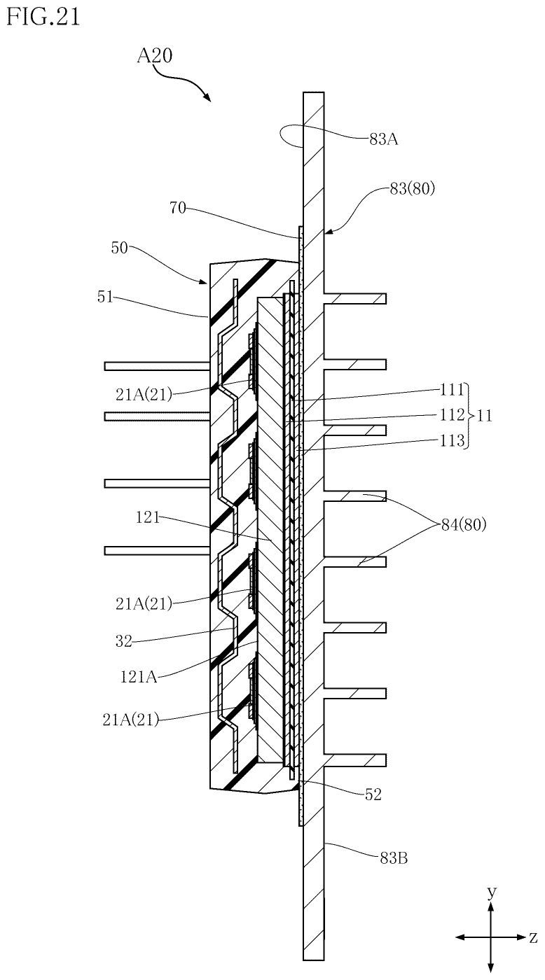

Based on FIGS. 20 to 22, a cooling structure (hereinafter referred to as a “cooling structure A20”) for a semiconductor device according to a second embodiment of the present disclosure is described. In these Figures, the elements identical or similar to those of the cooling structure A10 described above are marked with the same reference numerals, and redundant descriptions are omitted.

In the cooling structure A20, the configuration of cooler 80 is different from the configuration of the cooling structure A10.

As shown in FIGS. 20 to 22, the cooler 80 can have a base portion 83 and a radiation portion 84 instead of the housing 81 and the heat dissipating member 82. The base portion 83 can be flat. The base portion 83 can have a mounting surface 83A and a reverse surface 83B. The mounting surface 83A and the reverse surface 83B can face opposite each other in the first direction z. The mounting surface 83A can be opposed to the radiation layer 113 of the base material 11. The second surface 72 of the bonding material 70 can be in contact with the mounting surface 83A.

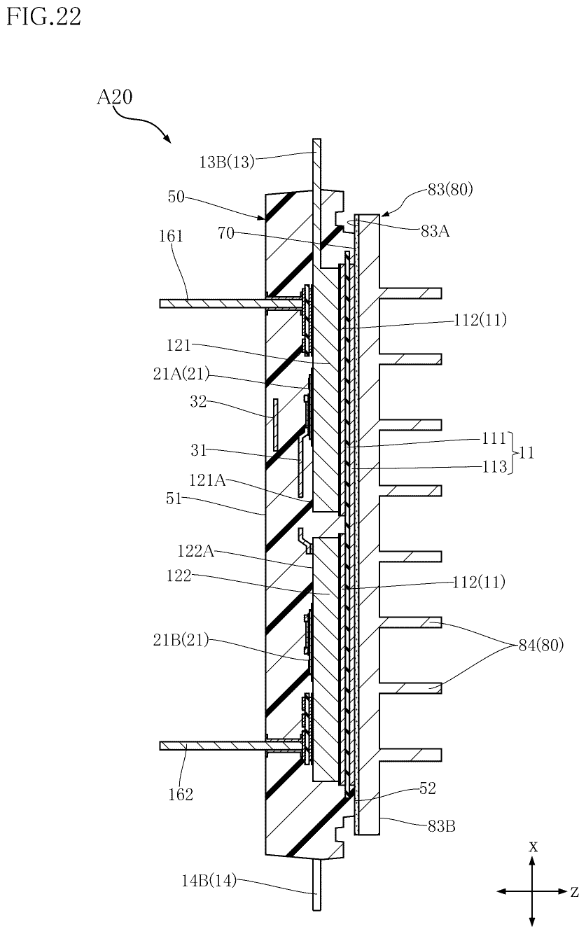

As shown in FIGS. 21 and 22, the radiation portion 84 can project from the reverse surface 83B of the base portion 83 in the first direction z. The radiation portion 84 can be positioned opposite the base material 11 with respect to the base portion 83 in the first direction z. The radiation portion 84 can be exposed to the outside. The radiation portion 84 can be a plurality of pins spaced apart from each other in a direction orthogonal to the first direction z. As shown in FIG. 20, as viewed in the first direction z, the radiation portion 84 can overlap each of the first conductive layer 121 and the second conductive layer 122.

Subsequently, the effects of the cooling structure A20 will be described.

The cooling structure A20 can have the semiconductor device B having the base material 11 and the sealing resin 50, the cooler 80, and the bonding material 70 that bonds the cooler 80 and the base material 11. As viewed in the first direction z, the bonding material 70 can extend outwardly from the sealing resin 50. The bonding material 70 can have the first surface 71 in contact with the base material 11 and the second surface 72 in contact with the cooler 80. The area of the second surface 72 can be larger than the area of the first surface 71. Therefore, according to this configuration, in the cooling structure A20 as well, it is possible to easily check the bonding state of the semiconductor device B with respect to the cooler 80, while increasing the cooling efficiency of the semiconductor device B. Further, the cooling structure A20 exhibits the same effect as that of the cooling structure A10 by having the configuration common with that of the cooling structure A10.

The cooling structure A20 can have the base portion 83 in contact with the second surface 72 of the bonding material 70, and the radiation portion 84 protruding in the first direction z from the base portion 83. The radiation portion 84 can be exposed to the outside. As viewed in the first direction z, each of the first conductive layer 121 and the second conductive layer 122 can overlap the radiation portion 84. By adopting this configuration, the surface area of the cooler 80 is expanded, and thus the cooling efficiency of the semiconductor device B can be improved.

The present disclosure is not limited to the aforementioned embodiments. The specific configuration of each part of the disclosure can be designed and modified in various ways.

The present disclosure may include the embodiments described in the following clauses.

### Clause 1

A cooling structure for a semiconductor device comprising:
a semiconductor device comprising: a base material, a conductive layer bonded to the base material, a semiconductor element located on a side opposite the base material in a first direction with respect to the conductive layer and bonded to the conductive layer, and a sealing resin covering the conductive layer and the semiconductor element;
a cooler; and
a bonding material that bonds the cooler and the base material,
wherein as viewed in the first direction, the bonding material extends outwardly from the sealing resin,
the bonding material has a first surface and a second surface facing opposite each other in the first direction,
the first surface is in contact with the base material,
the second surface is in contact with the cooler, and
an area of the second surface is larger than an area of the first surface.

### Clause 2

The cooling structure for a semiconductor device according to clause 1, wherein as viewed in the first direction, an entity of the first surface overlaps the second surface.

### Clause 3

The cooling structure for a semiconductor device according to clause 2,
wherein the sealing resin has a bottom surface facing opposed to the cooler in the first direction, and
the first surface is in contact with the bottom surface.

### Clause 4

The cooling structure for a semiconductor device according to clause 3,
wherein the sealing resin has a top surface facing a side opposite a side the bottom surface faces in the first direction, and
an entirety of the top surface is exposed to an outside.

### Clause 5

The cooling structure for a semiconductor device according to clause 4, wherein as viewed in the first direction, a peripheral end of the second surface includes a section that is a convex curve.

### Clause 6

The cooling structure for a semiconductor device according to clause 5,
wherein the bonding material has an end surface facing a direction orthogonal to the first direction, and
the end surface bulges toward an outside of the bonding material.

### Clause 7

The cooling structure for a semiconductor device according to clause 6, wherein the semiconductor element is conductively bonded to the conductive layer.

### Clause 8

The cooling structure for a semiconductor device according to clause 7, wherein a dimension in the first direction of the conductive layer is larger than a dimension in the first direction of the base material.

### Clause 9

The cooling structure for a semiconductor device according to clause 8,
wherein the semiconductor device has a first input terminal and a second input terminal conducted to the conductive layer,
each of the first input terminal and the second input terminal has an exposed portion exposed from the sealing resin, and
as viewed in the first direction, the exposed portion is separated from the cooler and the bonding material.

### Clause 10

The cooling structure for a semiconductor device according to any one of clauses 1 to 9,
wherein the base material has an insulating layer, a metal layer laminated on the insulating layer, and a radiation layer located opposite the metal layer and laminated on the insulating layer,
the conductive layer is bonded to the metal layer, and
the first surface is in contact with the radiation layer.

### Clause 11

The cooling structure for a semiconductor device according to clause 10, wherein a dimension in the first direction of the bonding material is smaller than a dimension in the first direction of the radiation layer.

### Clause 12

The cooling structure for a semiconductor device according to clause 10,
wherein the cooler has a housing in contact with the second surface,
the housing has a hollow portion located inside the housing, and an inlet and an outlet leading to the hollow portion, and
as viewed in the first direction, the conductive layer overlaps the hollow portion.

### Clause 13

The cooling structure for a semiconductor device according to clause 12,
wherein the hollow portion is along a direction orthogonal to the first direction and include a steeply contracted portion having a smallest cross-sectional area in a section from the inlet to the outlet, and
as viewed in the first direction, the conductive layer overlaps the steeply contracted portion.

### Clause 14

The cooling structure for a semiconductor device according to clause 13,
wherein the cooler is housed in the steeply contracted portion and has a heat dissipating member connected to the housing, and
as viewed in the first direction, the conductive layer overlaps the heat dissipating member.

### Clause 15

The cooling structure for a semiconductor device according to clause 14,
wherein the heat dissipating member includes a plurality of fins, and
each of the plurality of fins extends in a direction orthogonal to the first direction and along a section from the inlet to the outlet.

### Clause 16

The cooling structure for a semiconductor device according to clause 10,
wherein the cooler has a base portion in contact with the second surface, and a radiation portion being located opposite the base material with respect to the base portion and protruding from the base portion in the first direction,
the radiation portion is exposed to an outside, and
as viewed in the first direction, the conductive layer overlaps the radiation portion.

REFERENCE NUMERALS

| | |
|---|---|
| A10, A20: Cooling structure | B: Semiconductor device |
| 11: Base material | 111: Insulating layer |
| 112: Metal layer | 113: Radiation layer |
| 121: First conductive layer | 121A: First obverse surface |
| 122: Second conductive layer | 122A: Second obverse surface |
| 123: Bonding layer | 13: First input terminal |
| 13A: Covered portion | 13B: Exposed portion |
| 14: Output terminal | 14A: Covered portion |
| 14B: Exposed portion | 15: Second input terminal |
| 15A: Covered portion | 15B: Exposed portion |
| 161: First signal terminal | 162: Second signal terminal |
| 171: Third signal terminal | 172: Fourth signal terminal |
| 181: Fifth signal terminal | 182: Sixth signal terminal |
| 19: Seventh signal terminal | 21: Semiconductor element |
| 21A: First element | 21B: Second element |
| 211: First electrode | 212: Second electrode |
| 213: Third electrode | 214: Fourth electrode |
| 22: Thermistor | 23: Conductive bonding layer |
| 31: First conductive member | 311: Body portion |
| 312: First bonding portion | 313: First coupling portion |
| 314: Second bonding portion | 315: Second coupling portion |
| 32: Second conductive member | 321: Body portion |
| 322: Third bonding portion | 323: Third coupling portion |
| 324: Fourth bonding portion | 325: Fourth coupling portion |
| 326: Intermediate portion | 327: Transverse beam portion |
| 33: First conductive bonding layer | 34: Second conductive bonding layer |
| 35: Third conductive bonding layer | 36: Fourth conductive bonding layer |
| 41: First wire | 42: Second wire |
| 43: Third wire | 44: Fourth wire |
| 50: Sealing resin | 51: Top surface |
| 52: Bottom surface | 53: First lateral surface |
| 54: Second lateral surface | 55: Recess |
| 60: Control wiring | 601: First wiring |
| 602: Second wiring | 61: Insulating layer |
| 62: Wiring layer | 621: First wiring layer |
| 622: Second wiring layer | 623: Third wiring layer |
| 624: Fourth wiring layer | 625: Fifth wiring layer |
| 63: Metal layer | 64: Sleeve |
| 641: End surface | 68: First adhesive layer |
| 69: Second adhesive layer | 70: Bonding material |
| 71: First surface | 72: Second surface |
| 721: Peripheral end | 73: End surface |
| 80: Cooler | 81: Housing |
| 81A: Mounting surface | 811: Hollow portion |
| 811A: Steeply contracted portion | 812: Inlet |
| 813: Outlet | 82: Heat dissipating member |
| 83: Base portion | 83A: Mounting surface |
| 83B: Reverse surface | 84: Radiation portion |
| z: First direction | x: Second direction |
| y: Third direction | |

1. A cooling structure for a semiconductor device comprising:
a semiconductor device comprising: a base material, a conductive layer bonded to the base material, a semiconductor element located on a side opposite the base material in a first direction with respect to the conductive layer and bonded to the conductive layer, and a sealing resin covering the conductive layer and the semiconductor element;
a cooler; and
a bonding material that bonds the cooler and the base material,
wherein as viewed in the first direction, the bonding material extends outwardly from the sealing resin,
the bonding material has a first surface and a second surface facing opposite each other in the first direction,
the first surface is in contact with the base material,
the second surface is in contact with the cooler, and
an area of the second surface is larger than an area of the first surface.

2. The cooling structure for a semiconductor device according to claim 1, wherein as viewed in the first direction, an entity of the first surface overlaps the second surface.

3. The cooling structure for a semiconductor device according to claim 2,
wherein the sealing resin has a bottom surface facing opposed to the cooler in the first direction, and
the first surface is in contact with the bottom surface.

4. The cooling structure for a semiconductor device according to claim 3,
wherein the sealing resin has a top surface facing a side opposite a side the bottom surface faces in the first direction, and
an entirety of the top surface is exposed to an outside.

5. The cooling structure for a semiconductor device according to claim 4, wherein as viewed in the first direction, a peripheral end of the second surface includes a section that is a convex curve.

6. The cooling structure for a semiconductor device according to claim 5,
wherein the bonding material has an end surface facing a direction orthogonal to the first direction, and
the end surface bulges toward an outside of the bonding material.

7. The cooling structure for a semiconductor device according to claim 6, wherein the semiconductor element is conductively bonded to the conductive layer.

8. The cooling structure for a semiconductor device according to claim 7, wherein a dimension in the first direction of the conductive layer is larger than a dimension in the first direction of the base material.

9. The cooling structure for a semiconductor device according to claim 8,
wherein the semiconductor device has a first input terminal and a second input terminal conducted to the conductive layer,
each of the first input terminal and the second input terminal has an exposed portion exposed from the sealing resin, and
as viewed in the first direction, the exposed portion is separated from the cooler and the bonding material.

10. The cooling structure for a semiconductor device according to claim 1,
wherein the base material has an insulating layer, a metal layer laminated on the insulating layer, and a radiation layer located opposite the metal layer and laminated on the insulating layer,
the conductive layer is bonded to the metal layer, and
the first surface is in contact with the radiation layer.

11. The cooling structure for a semiconductor device according to claim 10, wherein a dimension in the first direction of the bonding material is smaller than a dimension in the first direction of the radiation layer.

12. The cooling structure for a semiconductor device according to claim 10,
wherein the cooler has a housing with which the second surface contacts,
the housing has a hollow portion located inside the housing, and an inlet and an outlet each leading to the hollow portion, and
as viewed in the first direction, the conductive layer overlaps the hollow portion.

13. The cooling structure for a semiconductor device according to claim 12,
wherein the hollow portion is along a direction orthogonal to the first direction and include a steeply contracted portion having a smallest cross-sectional area in a section from the inlet to the outlet, and
as viewed in the first direction, the conductive layer overlaps the steeply contracted portion.

14. The cooling structure for a semiconductor device according to claim 13,
wherein the cooler is housed in the steeply contracted portion and has a heat dissipating member connected to the housing, and
as viewed in the first direction, the conductive layer overlaps the heat dissipating member.

15. The cooling structure for a semiconductor device according to claim 14,
wherein the heat dissipating member includes a plurality of fins, and
each of the plurality of fins extends in a direction orthogonal to the first direction and along a section from the inlet to the outlet.

16. The cooling structure for a semiconductor device according to claim 10,
wherein the cooler has a base portion in contact with the second surface, and a radiation portion being located opposite the base material with respect to the base portion and protruding from the base portion in the first direction,
the radiation portion is exposed to an outside, and
as viewed in the first direction, the conductive layer overlaps the radiation portion.
